(19) United States
(12) Patent Application Publication
(10) Pub. No.: US 2014/0055042 A1
(43) Pub. Date: Feb. 27, 2014

(54) CONTROLLING APPARATUS AND METHOD, RECORDING MEDIUM, PROGRAM AND INPUTTING AND OUTPUTTING APPARATUS

(71) Applicant: Sony Corporation, Tokyo (JP)

(72) Inventor: Mitsuru Tateuchi, Kanagawa (JP)

(73) Assignee: Sony Corporation, Tokyo (JP)

(21) Appl. No.: 14/069,496

(22) Filed: Nov. 1, 2013

Related U.S. Application Data
(63) Continuation of application No. 11/135,072, filed on May 23, 2005.

(30) Foreign Application Priority Data
May 27, 2004 (JP) 2004-157114

(51) Int. Cl. H01L 27/32

(52) U.S. Cl. CPC H01L 27/3269
USPC 315/153

(57) ABSTRACT

Disclosed herein is a controlling apparatus for controlling an inputting and outputting apparatus of the active matrix driving type including pixels each having an electroluminescence element whose operation can be changed over between light emitting operation and light receiving operation in response to a voltage applied thereto, including: a removing section for removing, when the light receiving operation is to be performed by the electroluminescence element included in a predetermined pixel, charge accumulated. in a parasitic capacitance upon the light emitting operation performed immediately before the light receiving operation by the electroluminescence element; and a detection section for detecting light inputted from the outside to the inputting and outputting apparatus based on an output from the predetermined pixel including the electroluminescence element whose charge has been removed from the parasitic capacitance thereof by the removing section.

### CROSS REFERENCE TO RELATED APPLICATIONS

This is a Continuation application of U.S. patent application Ser. No. 11/135,072, filed May 23, 2005, which in turn claims priority from Japanese Application No.: 2004-157114, filed on May 27, 2004, the entire contents of which are incorporated herein by reference.

### BACKGROUND OF THE INVENTION

The present invention relates to a controlling apparatus and method, a recording medium, a program and an inputting and outputting apparatus, and more particularly to a controlling apparatus and method, a recording medium and a program adapted to stabilize operation of an inputting and outputting apparatus which can display an image and besides detect light illuminated from the outside.

In recent years, various techniques have been proposed wherein various type of information can be directly inputted to a displaying apparatus without providing a touch panel or the like in an overlying relationship thereon. One of such techniques is disclosed in Japanese Patent Laid-Open No. Hei 11-53111 (hereinafter referred to as Patent Document 1) or Japanese Patent Laid-Open No. 2004-127272 (hereinafter referred to as Patent Document 2).

For example, Patent Document 2 discloses a display apparatus which can control the voltage to be applied to each pixel to cause the pixel to perform light emitting operation which is operation of displaying an image and light receiving operation which is operation of detecting light from the outside. In the display apparatus, when it performs the light receiving operation, a voltage in the reverse direction to that in the light emitting operation is applied to each pixel. Then, light from the outside is detected using leak current generated in each pixel when light is illuminated in a state wherein such a voltage in the reverse direction as just described is applied. Consequently, the user can directly input the data into the display apparatus by illuminating light which represents predetermined data upon the display apparatus.

Another technique for controlling operation of an EL (Electroluminescence) display apparatus wherein an EL element is provided in each of pixels similarly as in that disclosed in Patent Document 2 is disclosed in Japanese Patent Laid-Open No. Hei 9-232074 (hereinafter referred to as Patent Document 3). According to the technique disclosed in Patent Document 3, in order to improve the build-up of an EL element in an EL display apparatus of the simple matrix driving type from a state wherein the EL element does not emit light to another state wherein a voltage is applied to cause the EL element to emit light, charge accumulated in the parasitic capacitance of the EL element is removed immediately before light is emitted.

Further, a technique for suppressing degradation of an organic EL element to achieve long lifetime of the same is disclosed in Japanese Patent Laid-Open No. 2003-162253 (hereinafter referred to as Patent Document 4) or Japanese Patent Laid-Open No. 2003-122303 (hereinafter referred to as Patent Document 5). According to the technique disclosed Patent Document 4, a capacitor for applying a voltage in a direction wherein charge accumulated in a parasitic capacitance is canceled is provided for an organic EL element. Meanwhile, according to the technique disclosed in Patent Document 5, a voltage of a reverse bias is applied to an organic EL element.

Furthermore, a technique for detecting optically inputted information using an organic EL element which is a light emitting element is disclosed in Japanese Patent Laid-Open No. Hei 7-175420 (hereinafter referred to as Patent Document 6).

### SUMMARY OF THE INVENTION

Incidentally, a display apparatus which can control the voltage to be applied to perform changeover between the light emitting operation and the light receiving operation similarly to that disclosed in Patent Document 2 has a subject to be solved in that, when the operation mode of a certain pixel is to be changed over from the light emitting operation to the light receiving operation, charge accumulated in a parasitic capacitance of the EL element within a period of time of the light emitting operation till then has an influence on the light receiving operation.

Here, changeover of the operation of the EL element and charge accumulated in the parasitic capacitance of the EL element by the changeover are described.

FIGS. 1 and 2 show a circuit configuration of each pixel which forms an EL display apparatus and illustrate operation of the pixel. Referring to FIGS. 1 and 2, each pixel is represented by an EL element and a parasitic capacitance C_el connected in parallel to the EL element. FIG. 1 illustrates the light emitting operation and FIG. 2 illustrates the light receiving operation.

As seen in FIG. 1, where a bias in the forward direction is applied, light emission current I_ell flows in the forward direction to the EL element to cause the EL element to emit light. At this time, in the parasitic capacitance C_el, positive and negative charges individually having an amount corresponding to that of the light emitting current I_ell are accumulated on the anode electrode side and cathode electrode side of the EL element, respectively. For example, the potential difference between the electrodes of the EL element increases as the level of light emission increases (as the luminance increases). Therefore, also the amount of charge accumulated in the parasitic capacitance C_el increases.

On the other hand, if light is illuminated on the EL element from the outside in a state wherein a bias in the reverse direction is applied to the EL element, then light reception current I_e12 (leak current) in the opposite direction to that of the light emission current I_ell as seen in FIG. 2. At this time, the EL element does not emit light. Further, since the directions of the light emission current I_ell and the light reception current I_e12 are opposite to each other, charge of the polarity opposite to that in the light emitting operation is accumulated into the parasitic capacitance C_el.

Accordingly, when the operation mode is changed over from the light emitting operation to the light receiving operation (in the case of changeover from the state of FIG. 1 to the state of FIG. 2), charge accumulated in the parasitic capacitance C_el as seen in FIG. 1 during the light emitting operation till then has an influence so as to cancel part of the light reception current I_e12 which is generated in the light receiving operation.

Since usually the light reception current I_e12 is lower than that of the light emission current I_ell which flows upon emission of light, where part of the light reception current I_e12 is canceled in this manner, it becomes difficult to detect light from the outside based on the light reception current I_e12.

In particular, if the operation mode is changed over from the light emitting operation to the light receiving operation, then since charge accumulated in the parasitic capacitance C_el during the light emitting operation remains, the light reception sensitivity is deteriorated thereby. Also the degree of the deterioration of the light reception sensitivity differs depending upon the level of light emission (depending upon the amount of charge accumulated in the parasitic capacitance C_el), that is, depending upon the contents of an image displayed together with surrounding pixels and exhibits a dispersion. Therefore, stable operation cannot be assured.

It is desirable to provide a controlling apparatus and method, a recording medium, a program, and an inputting and outputting apparatus wherein light emitting operation of a display apparatus which can perform inputting and outputting operations does not have an influence upon light receiving operation performed immediately after the light emitting operation thereby to stabilize operation of the display apparatus.

In order to attain the desire described above, according to an embodiment of the present invention, there is provided a controlling apparatus for controlling an inputting and outputting apparatus of an active matrix driving type including pixels each including an electroluminescence element whose operation can be changed over between light emitting operation and light receiving operation in response to a voltage applied thereto, including a removing section for removing, when the light receiving operation is to be performed by the electroluminescence element included in a predetermined pixel, charge accumulated in a parasitic capacitance upon the light emitting operation performed immediately before the light receiving operation by the electroluminescence element, and a detection section for detecting light inputted from the outside to the inputting and outputting apparatus based on an output from the predetermined pixel including the electroluminescence element whose charge has been removed from the parasitic capacitance thereof by the removing section.

According to another embodiment of the present invention, there is provided a controlling method for a controlling apparatus for controlling an inputting and outputting apparatus of the active matrix driving type including pixels each including an electroluminescence element whose operation can be changed over between light emitting operation and light receiving operation in response to a voltage applied thereto, including a removing step of removing, when the light receiving operation is to be performed by the electroluminescence element included in a predetermined pixel, charge accumulated in a parasitic capacitance upon the light emitting operation performed immediately before the light receiving operation by the electroluminescence element, and a detection step of detecting light inputted from the outside to the inputting and outputting apparatus based on an output from the predetermined pixel including the electroluminescence element whose charge has been removed from the parasitic capacitance thereof by the process at the removing step.

According to a further embodiment of the present invention, there is provided a recording medium on which a program readable by and to be executed by a computer for controlling an inputting and outputting apparatus of an active matrix driving type including pixels each including an electroluminescence element whose operation can be changed over between light emitting operation and light receiving operation in response to a voltage applied thereto is recorded, the program including a removing controlling step of controlling, when the light receiving operation is to be performed by the electroluminescence element included in a predetermined pixel, removal of charge accumulated in a parasitic capacitance upon the light emitting operation performed immediately before the light receiving operation by the electroluminescence element, and a detection step of detecting light inputted from the outside to the inputting and outputting apparatus based on an output from the predetermined pixel including the electroluminescence element whose charge has been removed from the parasitic capacitance thereof by the process at the removing controlling step.

According to a still further embodiment of the present invention, there is provided a program for being executed by a computer for controlling an inputting and outputting apparatus of an active matrix driving type including pixels each including an electroluminescence element whose operation can be changed over between light emitting operation and light receiving operation in response to a voltage applied thereto is recorded, including a removing controlling step of controlling, when the light receiving operation is to be performed by the electroluminescence element included in a predetermined pixel, removal of charge accumulated in a parasitic capacitance upon the light emitting operation performed immediately before the light receiving operation by the electroluminescence element, and a detection step of detecting light inputted from the outside to the inputting and outputting apparatus based on an output from the predetermined pixel including the electroluminescence element whose charge has been removed from the parasitic capacitance thereof by the process at the removing controlling step.

With the controlling apparatus and method, recording medium and program, when the electroluminescence element included in a predetermined pixel is to perform the light receiving operation, charge accumulated in the parasitic capacitance accumulated upon the light receiving operation immediately before the light receiving operation by the electroluminescence element is removed. Thus, the input of the light from the outside to the inputting and outputting apparatus is detected based on the output of the predetermined pixel including the electroluminescence element wherein the charge has been removed from the parasitic capacitance.

According to a yet further embodiment of the present invention, there is provided an inputting and outputting apparatus of the active matrix driving type which includes pixels each including an electroluminescence element whose operation can be changed over between light emitting operation and light receiving operation in response to a voltage applied thereto, each of the pixels including a discharging section for discharging, when the light receiving operation is to be performed, charge accumulated in a parasitic capacitance of the electroluminescence element upon light emitting operation immediately before the light receiving operation under the control of a controlling apparatus, and an outputting section for outputting a signal representative of current generated in the pixel in response to light illuminated thereupon from the outside.

In the inputting and outputting apparatus, each of the pixels includes a discharging section for discharging, when the light receiving operation is to be performed, charge accumulated in a parasitic capacitance of the electroluminescence element upon light emitting operation immediately before the light receiving operation under the control of a controlling apparatus, and an outputting section for outputting a signal representative of current generated in the pixel in response to light illuminated thereupon from the outside.

With the controlling apparatus and method, recording medium, program and inputting and outputting apparatus, both of displaying of an image and detection of light from the outside can be achieved.

Further, with the controlling apparatus and method, recording medium, program and inputting and outputting apparatus, also when the operation mode of each pixel is changed over from the light emitting operation to the light receiving operation, the light receiving operation till then can be prevented from having an influence on the later light receiving operation.

Furthermore, with the controlling apparatus and method, recording medium, program and inputting and outputting apparatus, stabilized operation of the inputting and outputting apparatus can be assured.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIGS. 1 and 2 are circuit diagrams illustrating different operations of a circuit provided in a pixel;

FIG. 3 is a schematic view showing an example of an appearance of an I/O display apparatus to which the present invention is applied;

FIGS. 4 and 5 are circuit diagrams illustrating an OUT function and an IN function of a pixel of the I/O display apparatus of FIG. 3;

FIG. 6 is a graph illustrating an example of a current characteristic of the pixel of FIGS. 4 and 5;

FIG. 7 is a graph showing part of the graph of FIG. 6;

FIGS. 8 to 11 are circuit diagrams illustrating different operations of the circuit provided in the pixel of FIGS. 4 and 5;

FIG. 12 is a circuit diagram showing a particular example of the circuit provided in the pixel of FIGS. 4 and 5;

FIGS. 13 to 16 are circuit diagrams illustrating different operations of the circuit of FIG. 12;

FIG. 17 is a block diagram showing an example of a configuration of a control apparatus provided in the I/O display apparatus of FIG. 2;

FIG. 18 is a block diagram showing a functional configuration of the control apparatus of FIG. 17; and

FIG. 19 is a flow chart illustrating a control process executed by the control apparatus of FIG. 17.

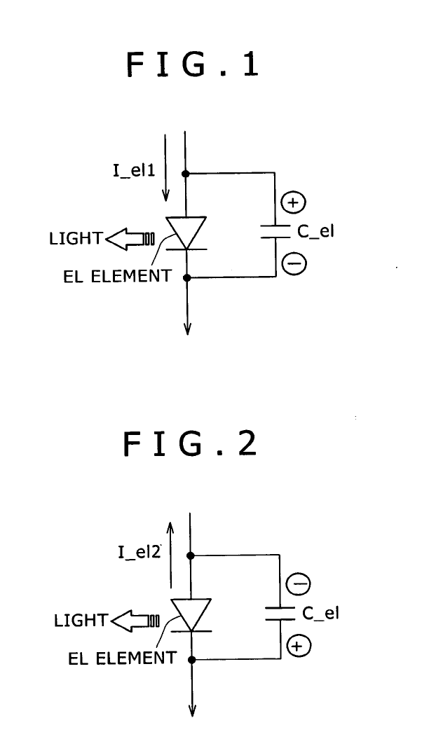

### DETAILED DESCRIPTION OF THE PREFERRED EMBODIMENTS

Before a preferred embodiment of the present invention is described in detail, a corresponding relationship between several features recited in the accompanying claims and particular elements of the preferred embodiment described below is described. The description, however, is merely for the confirmation that the particular elements which support the invention as recited in the claims are disclosed in the description of the embodiment of the present invention. Accordingly, even if some particular element which is recited in description of the embodiment is not recited as one of the features in the following description, this does not signify that the particular element does not correspond to the feature. On the contrary, even if some particular element is recited as an element corresponding to one of the features, this does not signify that the element does not correspond to any other feature than the element.

Further, the following description does not signify that the prevent invention corresponding to particular elements described in the embodiment of the present invention is all described in the claims. In other words, the following description does not deny the presence of an invention which corresponds to a particular element described in the description of the embodiment of the present invention but is not recited in the claims, that is, the description does not deny the presence of an invention which may be filed for patent in a divisional patent application or may be additionally included into the present patent application as a result of later amendment to the claims.

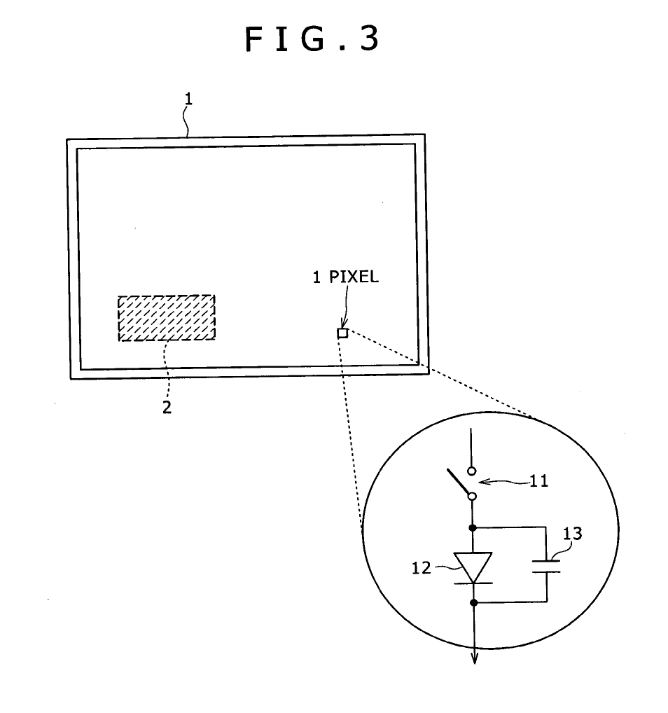

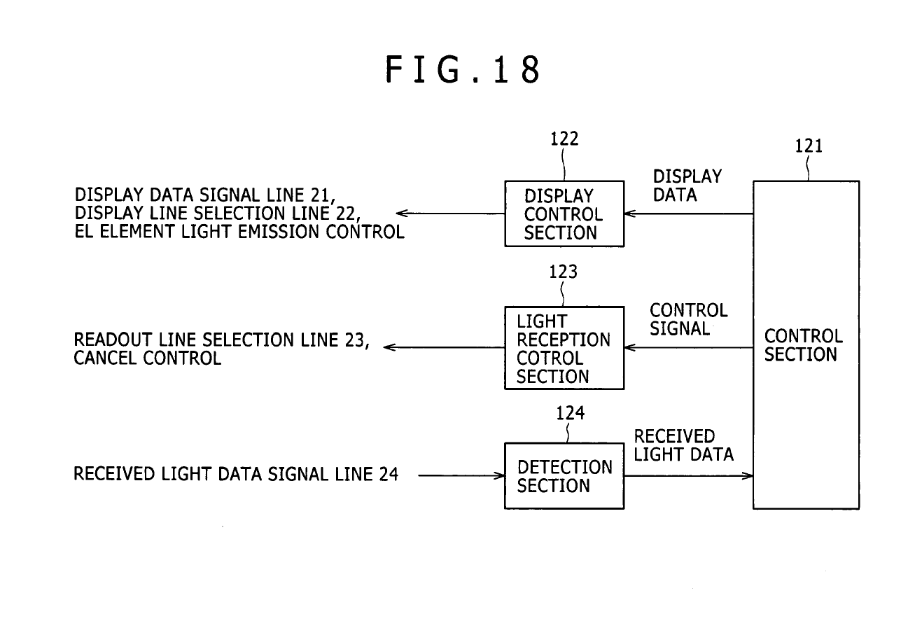

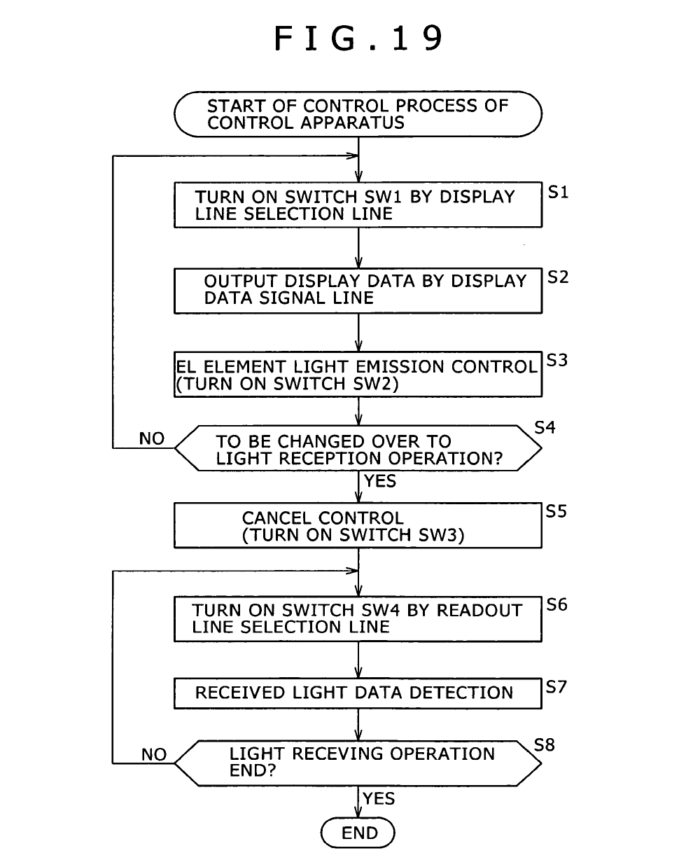

A controlling apparatus according to claim 1 is a controlling apparatus (for example, a control apparatus 2 of FIG. 3) for controlling an inputting and outputting apparatus (for example, an I/O display apparatus 1 of FIG. 3) of the active matrix driving type including pixels each including an EL (electroluminescence) element whose operation can be changed over between light emitting operation and light receiving operation in response to a voltage applied thereto, and includes a removing section (for example, a light reception control section 123 of FIG. 18 which performs a process at step S5 of FIG. 19) for removing, when the light receiving operation is to be performed by the EL element included in a predetermined pixel, charge accumulated in a parasitic capacitance upon the light emitting operation performed immediately before the light receiving operation by the EL element, and a detection section (for example, a detection section 124 of FIG. 18) for detecting light inputted from the outside to the inputting and outputting apparatus based on an output (for example, a signal corresponding to at least one of leak current of the EL element and leak current of a TFT) from the predetermined pixel including the EL element whose charge has been removed from the parasitic capacitance thereof by the removing section.

A controlling method according to claim 5 is a controlling method for a controlling apparatus (for example, a control apparatus 2 of FIG. 3) for controlling an inputting and outputting apparatus (for example, an I/O display apparatus 1 of FIG. 3) of the active matrix driving type including pixels each including an EL element whose operation can be changed over between light emitting operation and light receiving operation in response to a voltage applied thereto, and includes a removing step (for example, a step S5 of FIG. 19) of removing, when the light receiving operation is to be performed by the EL element included in a predetermined pixel, charge accumulated in a parasitic capacitance upon the light emitting operation performed immediately before the light receiving operation by the EL element, and a detection step (for example, a step S7 of FIG. 19) of detecting light inputted from the outside to the inputting and outputting apparatus based on an output (for example, a signal corresponding to at least one of leak current of the EL element and leak current of a TFT) from the predetermined pixel including the EL element whose charge has been extracted from the parasitic capacitance thereof by the process at the removing step.

Also in a program recorded in or on a recording medium according to claim 6 and a program according to claim 7, steps involved in the embodiment (mere example) hereinafter described are similar to those of the controlling method according to claim 5.

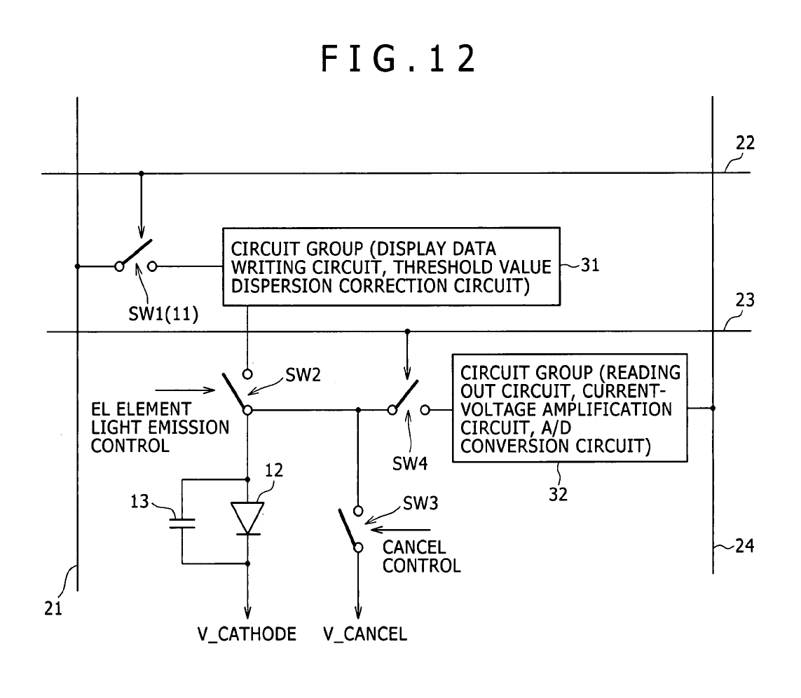

An inputting and outputting apparatus according to claim 8 is an inputting and outputting apparatus (for example, an I/O display apparatus 1 of FIG. 3) of the active matrix driving type which includes pixels each including an EL element whose operation can be changed over between light emitting operation and light receiving operation in response to a voltage applied thereto, each of the pixels including a discharging section (for example, a switch SW3 of FIG. 12) for discharging, when the light receiving operation is to be performed, charge accumulated in a parasitic capacitance of the EL element upon light emitting operation immediately before the light receiving operation under the control of a controlling apparatus, and an outputting section (for example, a switch SW4 of FIG. 12) for outputting a signal (for example, a signal corresponding to at least one of leak current of the EL element and leak current of a TFT) representative of current generated in the pixel in response to light illuminated thereupon from the outside.

In the following, an embodiment of the present invention is described with reference to the accompanying drawings.

FIG. 3 shows an example of an appearance of an I/O display apparatus 1 to which the present invention is applied.

Referring to FIG. 3, the I/O display unit 1 is a display unit which can implement an IN function (detection function) of detecting light illuminated from the outside and an OUT function (displaying function) of displaying a predetermined image using pixels which form the I/O display unit 1.

As shown in an enlarged fashion in a circle in FIG. 3, each of the pixels which form the I/O display unit 1 is represented by a switch 11 formed from, for example, a TFT (Thin Film Transistor), an organic or inorganic EL element 12, and a parasitic capacitance 13 parasitic on the EL element 12. In other words, the I/O display unit 1 is an EL display unit of the self-luminous type which allows active matrix driving.

In the I/O display unit 1, operation of the pixels is controlled by a control apparatus 2 to implement the IN function and the OUT function.

Here, the IN function and the OUT function are described.

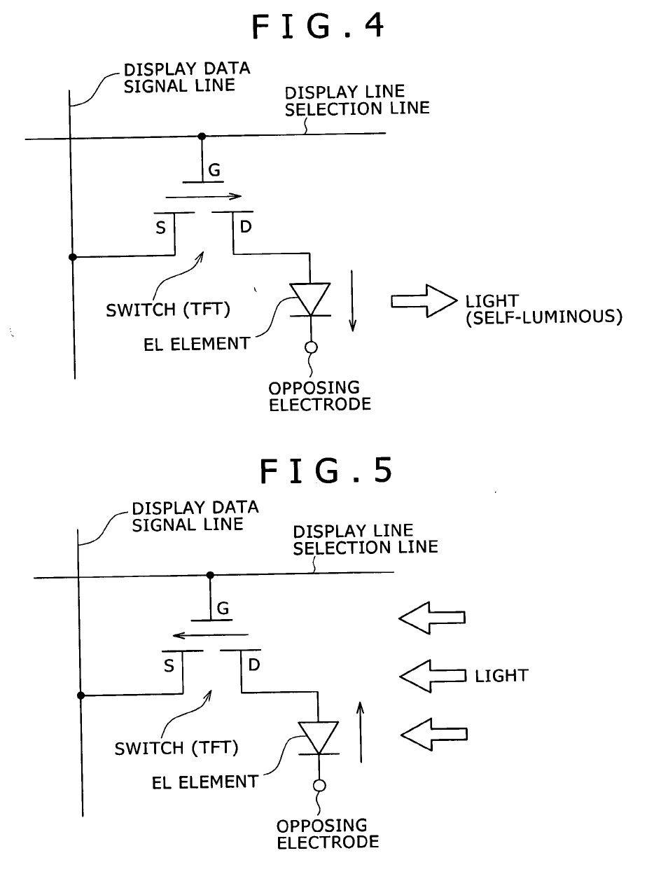

FIGS. 4 and 5 show an example of a circuit corresponding to one pixel of the I/O display apparatus 1.

When a voltage (bias) in the forward direction is applied to the gate electrode G of a TFT through a display line selection line (gate line), current flows in a direction from the source electrode S toward the drain electrode D within an active semiconductor layer (channel) made of amorphous silicon or polycrystalline silicon as indicated by an arrow mark of a solid line of FIG. 4 through a display data signal line (source line) in response to the voltage applied to the source electrode S.

The anode electrode of an EL element is connected to the drain electrode D of the TFT, and the EL element emits light as indicated by a void arrow mark in FIG. 4 in response to a potential difference between the anode and cathode electrodes which is generated by the current flowing through the channel of the TFT.

The light from the EL element is emitted to the outside of the display unit. Accordingly, displaying of an image, that is, the OUT function, is implemented by such operation of the pixel as described above.

On the other hand, where a voltage in the proximity of 0 V or in the reverse direction is applied to the gate electrode G of the TFT through the display line selection line, also when a voltage is applied to the source electrode S through the display data signal line, current does not flow in the channel, and no potential difference appears between the anode and cathode electrodes of the EL element. Consequently, no light is emitted from the EL element.

If, in this state, light from the outside is illuminated on the pixel of FIG. 5 as indicated by a void arrow mark, then leak current (off current) flows from the drain electrode D toward the source electrode S by the photoconductivity of the channel of the TFT although the current amount is very small. Similarly, leak current is generated also in the EL element.

From this, if the leak current generated by a pixel (TFT, EL element) to which a voltage in the proximity of 0 V or in the reverse direction is applied is amplified to detect whether or not such leak current exists, then it can be identified whether or not light is illuminated on the pixel from the outside. Further, also the amount of light can be identified depending upon the amount of leak current. In other words, the IN function is implemented by the operation.

For example, if the user illuminates light representative of predetermined data upon a display apparatus including pixels having such a configuration as described above, then the illuminated light can be detected by the display apparatus. Consequently, data can be inputted through light.

In the following description, operation of a pixel (EL element) when a voltage in the forward direction is applied as seen in FIG. 4 is referred to as light emitting operation, and operation of a pixel when a voltage in the reverse direction is applied and leak current is generated in response to light illuminated from the outside as seen in FIG. 5 is referred to as light receiving operation.

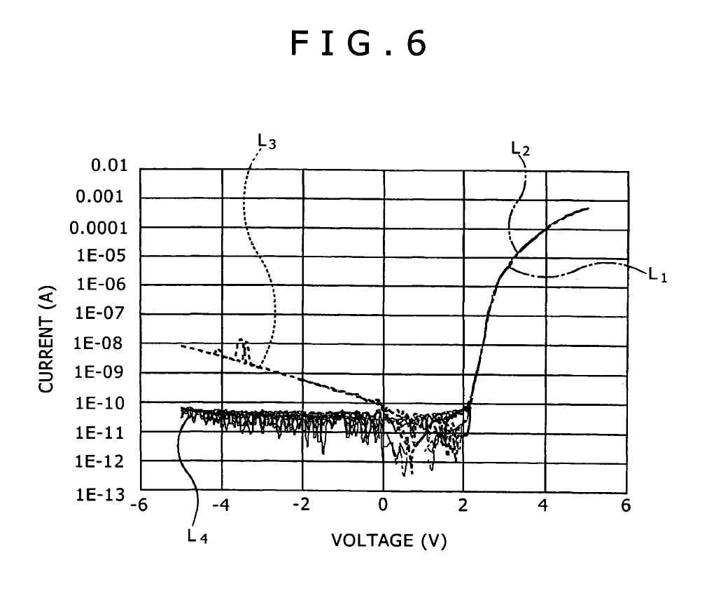

FIG. 6 illustrates a current characteristic of the pixel shown in FIGS. 4 and 5. In FIG. 6, the axis of ordinate represents the current in the pixel, and the axis of abscissa represents the voltage applied to the gate electrode G.

A line L₁ representative of a result of a measurement represents the value of current (current flowing through the channel of the TFT and current flowing through the EL element) detected by the pixel when light is illuminated on the pixel while a voltage in the forward direction is applied. Another line L₂ represents the value of current detected by the pixel when light is not illuminated on the pixel while a voltage in the forward direction is applied.

From the lines L¹ and L₂, it can be recognized that, when a voltage in the forward direction is applied, the current values detected exhibit no difference irrespective of whether or not light from the outside exists.

On the other hand, a further line L₃ in FIG. 6 represents the value of current detected by the pixel when light is illuminated on the pixel from the outside while a voltage in the reverse direction is applied. A still further line L₄ represents the value of current detected by the pixel when light is not illuminated on the pixel from the outside while a voltage in the reverse direction is applied.

As can be recognized from comparison between the lines L₃ and L₄, where a voltage in the reverse direction is applied, a difference is found between current values detected at the pixel depending upon whether or not light is illuminated on the pixel from the outside. For example, if light of a predetermined amount is illuminated upon the pixel from the outside while a voltage of approximately −5 V (voltage in the reverse direction) is applied, then current (current generated in the active semiconductor layer of the TFT and current generated by the EL element) of approximately “lE-8 (A)” is generated.

In FIG. 6, it is indicated by the line L₄ that, even when light is not illuminated from the outside, very low current of approximately “1E-lO (A)” is generated. However, this originates from noise during the measurement. It is to be noted that, of whichever one of the colors of R, G and B the pixel of the EL element emits light, an experiment result substantially similar to that illustrated in FIG. 6 is obtained.

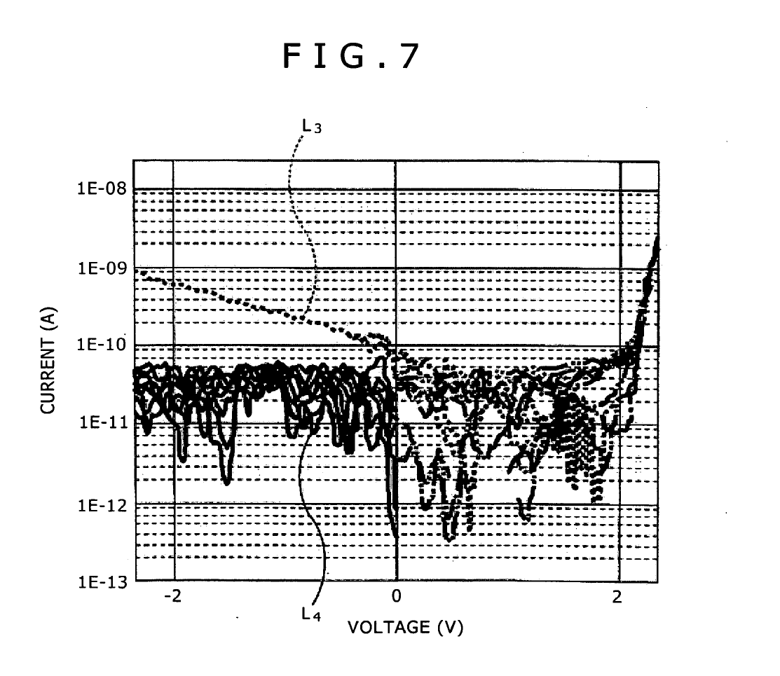

FIG. 7 shows a portion of the view of FIG. 6 in the proximity of the voltage of 0 V in an enlarged fashion.

As can be seen from the line L₃ and the line L₄ shown in FIG. 7, also where a voltage in the proximity of 0 V is applied to the pixel, a difference in current value is detected depending upon whether or not light is illuminated.

Accordingly, even when a voltage in the proximity of 0 V is applied, if current generated is amplified, then the difference in current, that is, whether or not light is illuminated, can be detected.

From this, by controlling the gate voltage so as to have a value in the proximity of 0 V without positively applying a voltage in the reverse direction, it is possible to cause a certain pixel to perform the light receiving operation.

By controlling the gate voltage so as to have a value in the proximity of 0 V to cause the pixel to perform light receiving operation, when compared with an alternative case wherein a voltage in the reverse direction is applied to cause the pixel to perform the operation, the power consumption can be suppressed by an amount provided by the voltage in the reverse direction.

Further, since the number of voltages to be controlled decreases, the control and besides the system configuration are facilitated. In particular, since to control the gate voltage so as to have a value in the proximity of 0 V is to control the gate voltage so that a voltage in the forward direction may not be applied, the control can be implemented only by a control line and a power supply circuit for controlling the gate voltage so that a voltage in the forward direction may be applied (there is no necessity to separately provide a control line for controlling the gate voltage so that a voltage in the reverse direction may be applied).

Consequently, a power supply circuit on a driver board of a display unit or on a system board can be simplified in configuration, and low power compensation can be implemented. Besides, also efficient utilization of a limited space on the board can be achieved.

Further, since a voltage in the reverse direction is not applied, breakdown of a TFT or an EL element which may possibly occur when a voltage in the reverse direction is applied can be prevented. Although the voltage resisting property of a TFT can be raised alternatively by increasing the channel length (L length), this decreases current in a conducting state, and in order to assure sufficient current, it is necessary to increase the channel width (W width).

As a result, in order to raise the voltage withstanding property without changing the value of current to flow through the TFT, it is necessary to increase the size of the TFT. This makes it difficult to dispose the TFT in each of pixels of a high definition display unit whose pixel size is small.

Accordingly, by eliminating a voltage in the reverse direction, design of the voltage withstanding property of a TFT and an EL element is facilitated, and besides the size itself of a TFT or an EL element can be reduced. As a result, a display apparatus having a high definition can be implemented.

As described above, according to the I/O display apparatus 1 wherein a TFT and an EL element are provided in each pixel, not only an image can be displayed, but also light from the outside can be detected using the pixels by applying a voltage in the proximity of 0 V or a voltage in the reverse direction.

Incidentally, in such a display unit which includes pixels which can perform both of light emitting operation and light receiving operation as described above, if the operation mode is changed over from the light emitting operation to the light receiving operation, then the light receiving sensitivity of each pixel is decreased by charge which has been accumulated in the parasitic capacitance of the EL element during the light emitting operation till then. Thus, in the I/O display apparatus 1 of FIG. 3, before the light receiving operation after the light emitting operation, the charge accumulated in the parasitic capacitance of the EL element during the light emitting operation till then is canceled or removed. In other words, a path for removing charge from a parasitic capacitance is provided for each pixel.

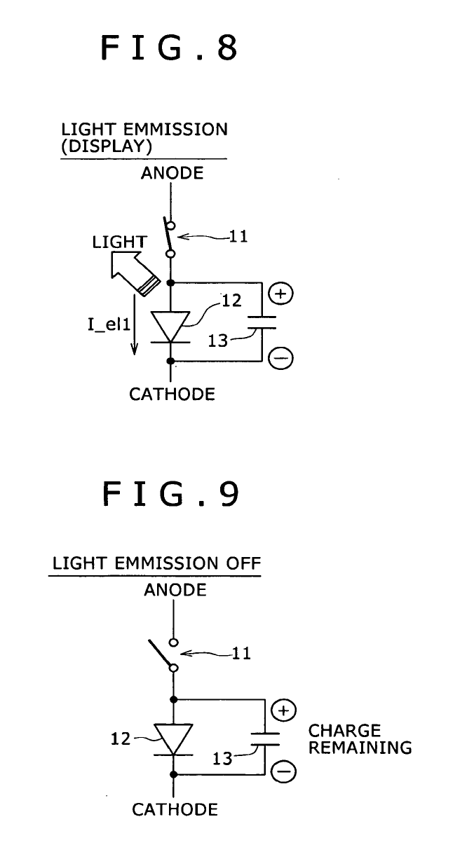

Now, a series of operations of the circuit after light emission till light reception is described with reference to FIGS. 8 to 11. The corresponding components to the components of the circuit shown in FIG. 3 are denoted by the same numbers.

It is assumed that, in the series of operations illustrated in FIGS. 8 to 11, detection of light from the outside is performed based only on leak current generated by the EL element 12. Also it is assumed that the light receiving operation is performed not by positively applying a bias in the reverse direction but by applying a voltage in the proximity of 0 V to the switch 11 (TFT) (by rendering the switch 11 non-conducting).

FIG. 8 illustrates an example of a state of the circuit when it performs the light emitting operation (displaying of an image).

Referring to FIG. 8, when the switch 11 is placed into a conducting state to apply a bias in the forward direction, light emission current I_ell in the forward direction flows through the EL element 12 thereby to cause the EL element 12 to emit light. At this time, positive charge is accumulated into the anode electrode side of the EL element 12 and negative charge is accumulated into the cathode electrode side of the EL element 12 each by an amount corresponding to the amount of the light emission current I_ell. For example, as the amount of the light emission current I_ell increases to raise the level of light emission (raise the luminance), the potential difference appearing between the two electrodes of the EL element 12 increases and also the amount of charge accumulated in the parasitic capacitance 13 increases.

FIG. 9 illustrates an example of a state of the circuit immediately after the light receiving operation is stopped.

Immediately after the switch 11 is placed into a non-conducting state to stop the light emitting operation, the charge accumulated in the parasitic capacitance 13 by the light emitting operation (FIG. 8) till then remains as it is as seen in FIG. 9. Naturally, if the impedance of the cathode electrode side is lower than that of the anode side, then the charge on the cathode electrode side escapes. However, since at least the anode electrode side does not have a path along which the remaining charge discharges, the charge remains. Accordingly, in order to eliminate an influence of the remaining charge from being had on the light receiving operation, operation of removing the charge is performed next.

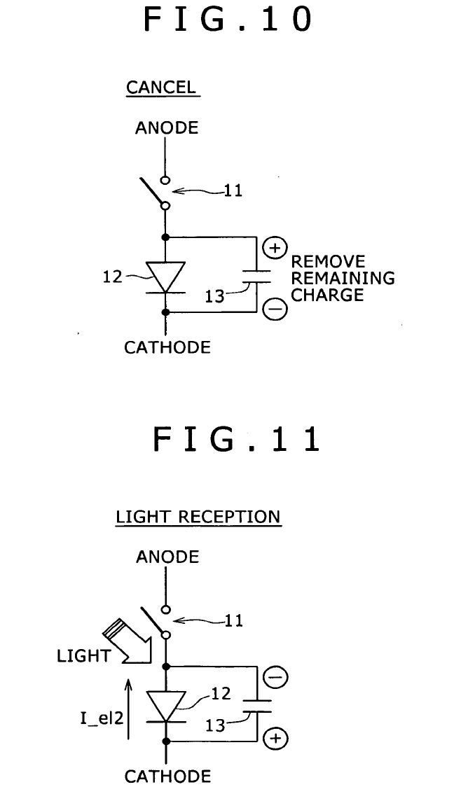

FIG. 10 illustrates a state of the circuit from which charge is removed.

By removing the charge remaining in the parasitic capacitance 13, for example, through a path not shown, the charge accumulated in the parasitic capacitance 13 during the light emitting operation disappears as seen in FIG. 10. Thereafter, light receiving operation is performed.

FIG. 11 illustrates an example of a state of the circuit when it performs light receiving operation.

If light is illuminated from the outside while a bias in the proximity of 0 V is applied (while the switch 11 is non-conducting) as seen in FIG. 11, then light reception current I_e12 in a direction opposite to that of the light emission current I_ell is generated. The light reception current I_e12 is amplified and so forth and extracted so that the light input from the outside is detected by the control apparatus 2.

It is to be noted that, when the bias in the proximity of 0 V is applied, the EL element 12 does not emit light. Further, since the directions of the light emission current I_ell and the light reception current I_e12 are opposite to each other, charge of the polarity opposite to that in the light emitting operation is accumulated into the parasitic capacitance 13.

Since, before the light receiving operation, charge accumulated in the parasitic capacitance 13 by the light emitting operation till then is removed in this manner, the charge accumulated in the parasitic capacitance 13 can be prevented from having an influence on the light reception current I_e12 which is to be generated in the light receiving operation.

Where such removal of charge as described above is not performed, the amount of the charge accumulated in the parasitic capacitance 13 differs depending upon the level of light emission of the EL element 12, and this gives rise to a dispersion in the light reception sensitivity in the light receiving operation. However, by removing charge before the light receiving operation, an input from the outside can be detected with a light reception sensitivity always fixed without being influenced by contents of the image to be displayed. Accordingly, also immediately after an image is displayed, whatever the image is, light reception current corresponding to the amount of illuminate light can be extracted, and consequently, operation of the I/O display apparatus 1 can be stabilized.

Furthermore, also if the light reception current is corrected taking the contents (level of light emission) of an image to be displayed into consideration such that, where the EL element has been emitting light, for example, with a high brightness level till then, the light reception current detected in light receiving operation immediately after the light emitting operation is amplified sufficiently, but where the EL element has been emitting light with a comparatively low brightness level till then, the light reception current detected in the light receiving operation immediately after the light emitting operation is not amplified very much, then detection which is not influenced by the contents of the image to be displayed can be achieved. However, where light emitting operation is performed after charge accumulated in the parasitic capacitance is removed, there is no necessity to provide a circuit which performs such correction as described above separately, for example, outside the pixel.

Now, a series of operations from light emission to light reception is described in connection with an example of a more particular circuit with reference to FIGS. 12 to 16.

FIG. 12 shows an example of a circuit in each of the pixels which form the I/O display apparatus 1. The corresponding components to the previously described components shown in FIGS. 8 to 11 are denoted by the same numbers.

Switches SW1 to SW4 are switching elements each formed from amorphous silicon or polycrystalline silicon.

In particular, the switch SWI (which corresponds to the switch 11 of FIG. 8) is controlled so as to be placed into a conducting/non-conducting state by a display line selection line 22. When the switch SW1 is in the conducting state, it outputs a signal representative of display data supplied thereto from a display data signal line 21 to a circuit group 31. The signal representing the display data is supplied, for example, from the control apparatus 2.

The switch SW2 is controlled so as to be placed into a conducting/non-conducting state by EL element light emission control by the control apparatus 2. The switch SW3 is controlled so as to be placed into a conducting/non-conducting state by cancellation control by the control apparatus 2. A path extending to the outside (V_cancel) of the pixel through the switch SW3 corresponds to the path for removing charge accumulated in the parasitic capacitance 13 described hereinabove. In other words, FIG. 12 shows an example wherein, since the impedance of the cathode electrode side of the EL element 12 is so low that charge accumulated on the cathode electrode side during the light emitting operation escapes automatically, a path for removing only charge accumulated in the anode electrode side of the parasitic capacitance 13 is formed.

The switch SW4 is controlled so as to be placed into a conducting/non-conducting state by a readout line selection line 23. When the switch SW4 is in a conducting state, leak current generated by the EL element 12 upon reception of the illuminated light is supplied to another circuit group 32. In other words, the switch SW4 is placed into a conducting state upon light receiving operation. It is to be noted that, where light from the outside is detected based not only on the EL element 12 but also on a switch SWI (TFT 11) which is placed into a conducting state upon light receiving operation, the circuit is configured such that also the current generated by the switch SWI is supplied to the circuit group 32 through the switch SW4.

The circuit group 31 includes, for example, a display data writing circuit, a threshold value dispersion correction circuit and so forth. The display data writing circuit performs I/V (current/voltage) conversion for temporarily storing a signal supplied thereto from the switch SWI to cause the EL element 12 to emit light. The threshold value dispersion correction circuit corrects a dispersion of a signal which appears, for example, with the output of the switch SWI (threshold value correction circuit of the TFT).

The circuit group 32 includes, for example, a reading out circuit, a current-voltage amplification circuit, an A/D (Analog/Digital) conversion circuit and so forth. The reading out circuit reads out a light reception signal generated by the EL element 12 through the switch SW4. The current-voltage amplification circuit amplifies reception light current or a voltage corresponding to the light reception current. The A/D conversion circuit converts the current value or voltage value amplified by the current-voltage amplification circuit into digital data (light reception data) and outputs the digital data to a reception light data signal line 24. The light reception data outputted to the reception light data signal line 24 is supplied to the control apparatus 2 so that the input of the light from the outside is detected by the control apparatus 2.

In FIG. 12, all of the switches SW1 to SW4 are in a non-conducting state. In this state, none of light emitting operation and light receiving operation is performed.

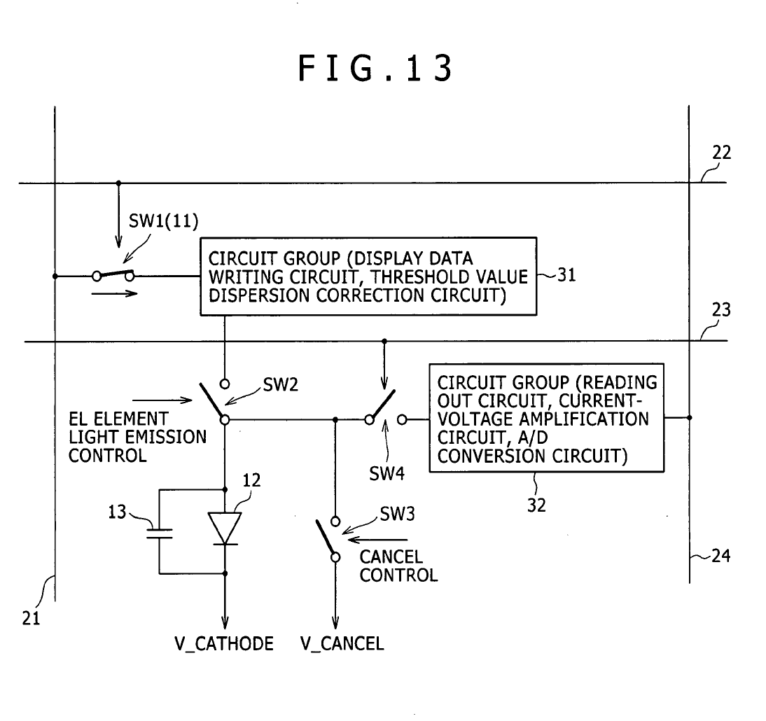

In order for the pixel in such a state as described above to perform light emitting operation, the switch SW1 is first placed into a conducting state by the display line selection line 22 as seen in FIG. 13. At this time, a signal representative of display data supplied thereto from the display data signal line 21 is inputted to the circuit group 31 through the switch SW1. The circuit group 31 performs I/V conversion and correction in dispersion.

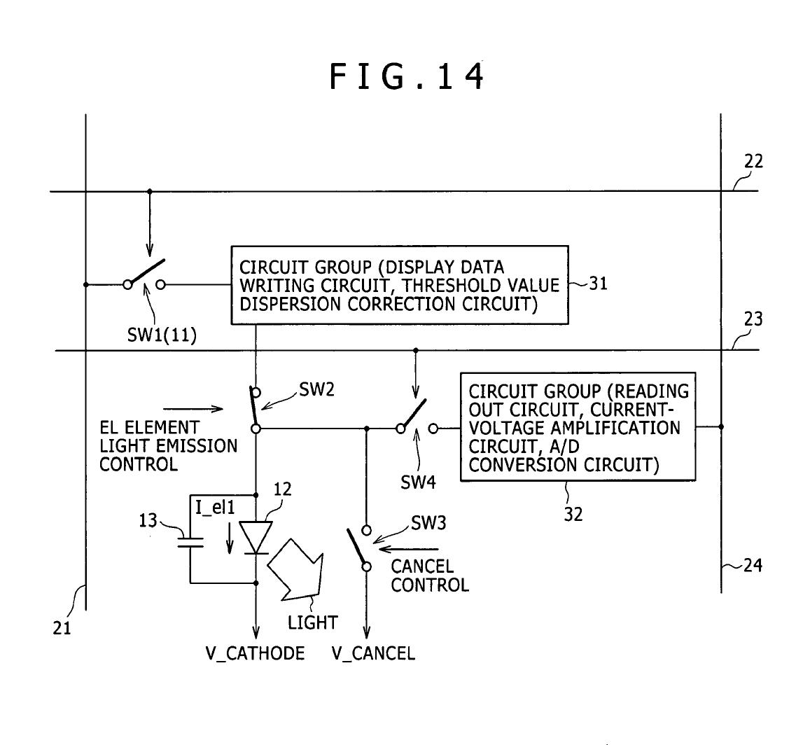

Then, after the switch SW1 is placed into a non-conducting state as seen in FIG. 14, EL element light emission control is performed by the control apparatus 2. Thus, in response to the switch SW2 placed into a conducting state, light emission current I_ell corresponding to the display data flows from the circuit group 31 to the EL element 12. Consequently, the EL element 12 emits light with a level corresponding to the display data.

At this time, a potential difference corresponding to the level of the light emission, that is, a potential difference corresponding to the display data, is applied between the anode and cathode electrodes of the EL element 12, and charge corresponding to the potential difference is accumulated into the parasitic capacitance 13. The state of FIG. 14 corresponds to the state of FIG. 8.

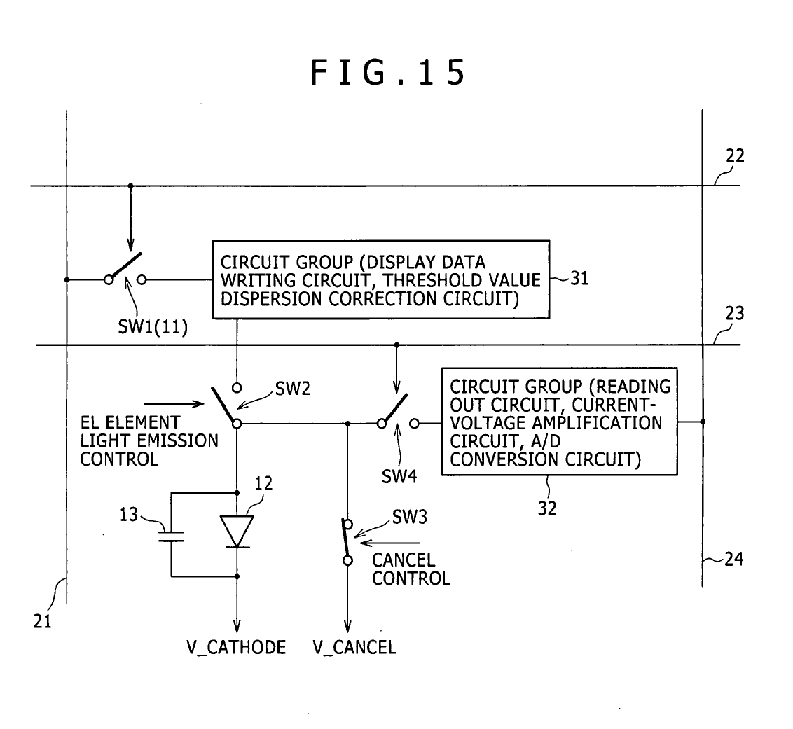

Then, after the switch SW2 is placed into a non-conducting state as seen in FIG. 15, cancellation control is performed by the control apparatus 2, and the switch SW3 is placed into a conducting state. Consequently, charge (positive charge on the anode electrode side) accumulated in the parasitic capacitance 13 of the EL element 12 is removed, and charge corresponding to a voltage V_cancel is accumulated into the parasitic capacitance 13. Here, if the voltage V_cancel is applied as a cathode voltage to the EL element 12, then charge is erased from the parasitic capacitance 13. The state of FIG. 15 corresponds to the state of FIG. 10.

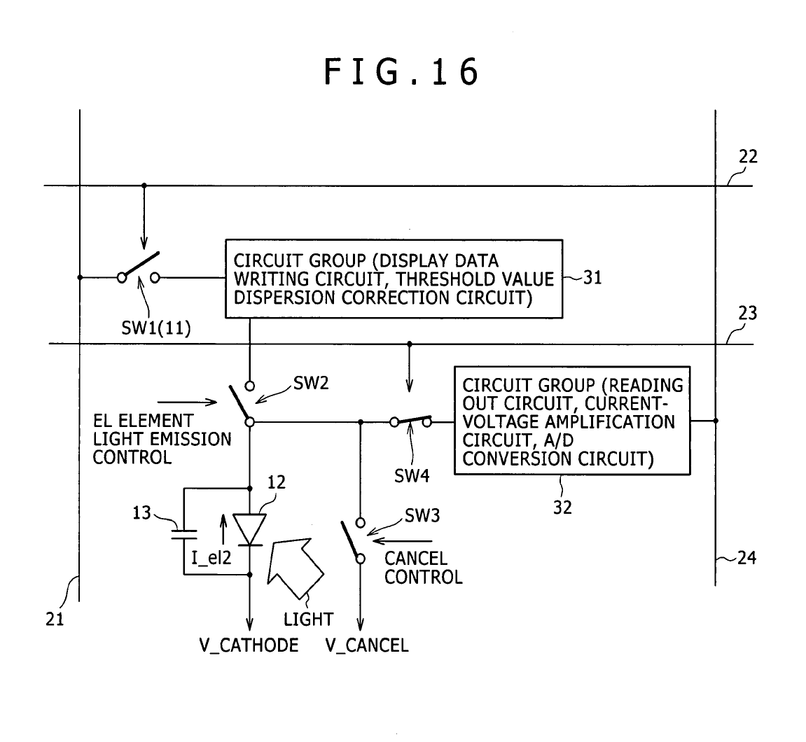

Thereafter, the switch SW4 is placed into a conducting state by the readout line selection line 23 as seen in FIG. 16, and consequently, a light reception signal I_e12 generated by the EL element 12 upon reception of the illuminated light is supplied to the circuit group 32 through the switch SW4. The circuit group 32 performs a predetermined process such as amplification for the light reception signal I_e12 supplied thereto and outputs resulting data to the control apparatus 2 through the reception light data signal line 24. The state of FIG. 16 corresponds to the state of FIG. 11.

By the operation described above, charge accumulated in the parasitic capacitance 13 during light emitting operation can be prevented from having an influence on the light reception current I_e12. The process of the control apparatus 2 for controlling the operation of each pixel in this manner is hereinafter described.

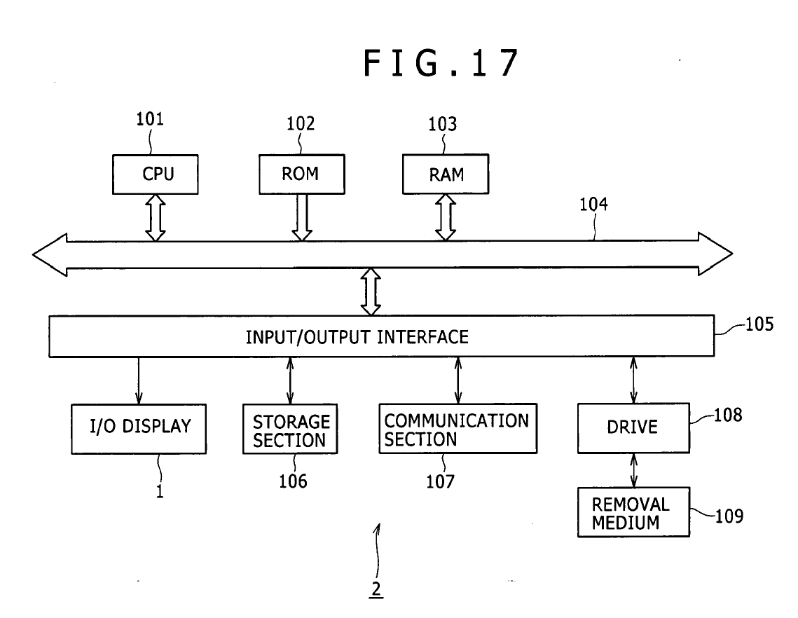

FIG. 17 shows an example of a configuration of the control apparatus 2.

Referring to FIG. 17, a central processing unit (CPU) 101 executes various processes in accordance with a program stored in a ROM (Read Only Memory) 102 or a program loaded from a storage section 106 into a RAM (Random Access Memory) 103. Also data necessary for the CPU 101 to execute the processes are suitably stored into the RAM 103.

The CPU 101, ROM 102 and RAM 103 are connected to one another by a bus 104. Also an input/output interface 105 is connected to the bus 104.

In addition to the I/O display apparatus 1, a storage section 106 formed from a hard disk, a communication section 107 for performing a communication process through a network and so forth are connected to the input/output interface 105.

As occasion demands, a drive 108 is connected to the input/output interface 105. A removable medium 109 such as a magnetic disk, an optical disk, a magneto-optical disk, a semiconductor memory or the like is suitably loaded into the drive 108, and a computer program read from the loaded medium is installed into the storage section 106 as occasion demands.

FIG. 18 shows an example of a functional configuration of the control apparatus 2.

At least part of components shown in FIG. 18 is implemented by execution of a predetermined program by the CPU 101 of FIG. 17.

A control section 121 outputs, for example, acquired data to a display control section 122 so that the display data are displayed using the pixels of the I/O display apparatus 1 which perform light emitting operation (causes each of the pixels to emit light with a level corresponding to the display data).

Further, the control section 121 controls a light reception control section 123 to cause predetermined ones of the pixels of the I/O display apparatus 1 to perform light receiving operation. When reception light data are supplied from a detection section 124, the control section 121 performs a predetermined process based on the reception light data.

The display control section 122 selects a line of those pixels from which light is to be emitted through the display line selection line 22 based on the display data supplied thereto from the control section 121 so that a signal representative of the display data is supplied from the display data signal line 21 thereby to cause the pixels of the selected line to perform light emitting operation. Further, the display control section 122 performs EL element light emitting control at a predetermined timing to place the switch SW2 into a conducting state.

The light reception control section 123 selects a line of those pixels which are to perform light receiving operation through the readout line selection line 23 under the control of the control section 121 thereby to cause the pixels of the selected line to perform light receiving operation. Further, the light reception control section 123 performs cancellation control at a predetermined timing to place the switch SW2 into a conducting state.

The detection section 124 detects data inputted from the outside through light based on the light reception data supplied thereto through the reception light data signal line 24, and outputs the detected light reception data to the control section 121.

Now, the control process of the I/O display apparatus 1 performed by the control apparatus 2 having such a configuration as described above is described with reference to a flow chart of FIG. 19. This process is started when display data are supplied from the control section 121 to the display control section 122 while the I/O display apparatus 1 is in such a state as seen in FIG. 12.

At step S1, the display control section 122 selects a line of those pixels which should perform light emitting operation by means of the display line selection line 22 based on display data supplied thereto from the control section 121, and places the switch SWI of each of the pixels of the selected light into a conducting state (ON) (FIG. 13).

Then at step S2, the display control section 122 supplies a signal representative of the display data through the display data signal line 21 to the pixels which should perform light emitting operation. Then, at step S3, the display control section 122 performs EL element light emitting control. Consequently, the switch SW2 in each of the pixels is placed into a conducting state, and light emission current I_ell obtained by the predetermined process performed by the circuit group 31 flows to the EL element 12 so that the EL element 12 emits light (FIG. 14).

It is to be noted that the display control section 122 places the switch SW1 into a non-conducting state (OFF) before the EL element light emission control and places the switch SW2 into a non-conducting state after the EL element 12 emits light.

At step S4, the display control section 122 decides whether or not the operation of the pixels having executed the light emitting operation should be changed over to light receiving operation. If it is decided that the operation should not be changed over, then the process returns to step S1 so that the process described above is repeated.

If it is decided at step S4 by the display control section 122 that the operation of the pixels having performed the light receiving operation should be changed over to light receiving operation, then the processing advances to step S5.

At step S5, the light reception control section 123 performs cancellation control to place the switch SW3 into a conducting state. Consequently, charge accumulated in the parasitic capacitance 13 in each of the pixels by the light emitting operation is removed (FIG. 15).

At step S6, the light reception control section 123 selects the line of those pixels having performed the light receiving operation through the readout line selection line 23 and places the switch SW4 of each of the pixels of the selected line into a conducting state thereby to cause the light reception current I_e12 generated by the EL element 12 upon illumination of light to be supplied to the circuit group 32. The light reception current I_e12 supplied to the circuit group 32 is subject to predetermined processes such as amplification, and resulting light reception data are supplied to the detection section 124 of the control apparatus 2 through the reception light data signal line 24 (FIG. 16).

At step S7, the detection section 124 detects the light reception data supplied thereto through the reception light data signal line 24 and outputs the detected light reception data to the control section 121.

At step S8, the light reception control section 123 decides whether or not the right receiving operation should be ended. If it is decided that the light receiving operation should not be ended, then the processing returns to step S6 so that the processes at the steps beginning with step S6 are performed. On the other hand, if it is decided that the right receiving operation should be ended, then the processing is ended.

By causing the process described above to be performed repetitively by each of the pixels, display of an image and detection of light can be performed. Further, it is possible to prevent charge accumulated in the parasitic capacitance 13 upon light emitting operation from having an influence on the light reception current I_e12.

While, in the foregoing description, removal of charge accumulated in the parasitic capacitance is performed only when the operation mode changes over from the light emitting operation to the light receiving operation, such removal of charge may be performed also when the operation mode changes over from the light receiving operation to the light emitting operation. This can be prevent charge accumulated in the parasitic capacitance during the light receiving operation from having an influence on the later light emitting operation.

Further, the removing timing of charge is not limited to that when the operation mode changes over, but may be every time before the light receiving operation which is performed repetitively. The amount of charge accumulated in the parasitic capacitance during light receiving operation is made different by the amount of light reception current, that is, by the amount of light illuminated from the outside, and when the light receiving operation is performed repetitively, charge accumulated in the parasitic capacitance during the preceding light receiving operation sometimes has an influence on the light reception current generated upon the next light receiving operation. However, also where removal of charge is normally performed before the light receiving operation, stabilized operation can be assured.

Furthermore, while, in the foregoing description, a path for removing charge accumulated in the parasitic capacitance therethrough is provided only on the anode electrode side of the EL element, also it is possible to provide, in addition to the path, another path also on the cathode electrode side.

Further, while the control apparatus 2 is built in the I/O display apparatus 1 as seen in FIG. 3, naturally the control apparatus 2 may otherwise be provided outside the I/O display apparatus 1.

While the series of processes described above can be executed by hardware, it may otherwise be executed by software.

Where the series of processes is executed by software, a program which constructs the software is installed from a network or a recording medium into a computer incorporated in hardware for exclusive use or, for example, a personal computer for universal use which can execute various functions by installing various programs.

The recording medium may be formed, as seen in FIG. 17, as a removable disk 109 which may be a magnetic disk (including a flexible disk), an optical disk (including a CD-ROM (Compact Disc-Read Only Memory) and a DVD (Digital Versatile Disk)), a magneto-optical disk (including an MD (Mini-Disc)), or a semiconductor memory which has the program recorded thereon or therein and is distributed in order to provide the program to a user separately from an apparatus body, or as a ROM 102 or a hard disk included in the storage section 106 which has the program recorded therein or thereon and is provided to a user in a form wherein it is incorporated in an apparatus body in advance.

It is to be noted that, in the present specification, the steps may be but need not necessarily be processed in a time series in the order as described, and include processes which are executed in parallel or individually without being processed in a time series.

While a preferred embodiment of the present invention has been described using specific terms, such description is for illustrative purposes only, and it is to be understood that changes and variations may be made without departing from the spirit or scope of the following claims.

What is claimed is:

1. A controlling apparatus for controlling an inputting and outputting apparatus of an active matrix driving type including pixels each including an electroluminescence element whose operation can be changed over between light emitting operation and light receiving operation in response to a voltage applied thereto, comprising:
removing means for removing, when the light receiving operation is to be performed by the electroluminescence element included in a predetermined pixel, charge accumulated in a parasitic capacitance upon the light emitting operation performed immediately before the light receiving operation by the electroluminescence element; and
detection means for detecting light inputted from the outside to the inputting and outputting apparatus based on an output from the predetermined pixel including the electroluminescence element whose charge has been removed from the parasitic capacitance thereof by said removing means.

2. The controlling apparatus according to claim 1, wherein said removing means removes charge accumulated in the parasitic capacitance when the operation of the electroluminescence element included in the predetermined pixel is changed over from the light emitting operation to the light receiving operation.

3. The controlling apparatus according to claim 1, wherein said detection means detects light inputted from the outside to the inputting and outputting apparatus based on the output from the predetermined pixel which represents current generated in response to reception of the light by the electroluminescence element whose charge has been removed from the parasitic capacitance thereof by said removing means.

4. The controlling apparatus according to claim 1, wherein said detection means detects light inputted from the outside to the inputting and outputting apparatus based on the output from the predetermined pixel which represents current generated in response to reception of the light by the electroluminescence element whose charge has been removed from the parasitic capacitance thereof by said removing means and current generated in response to reception of the light by a thin film transistor for changing over the operation of the pixel including the electroluminescence element.

5. A controlling method for a controlling apparatus for controlling an inputting and outputting apparatus of an active matrix driving type including pixels each including an electroluminescence element whose operation can be changed over between light emitting operation and light receiving operation in response to a voltage applied thereto, comprising steps of:
removing, when the light receiving operation is to be performed by the electroluminescence element included in a predetermined pixel, charge accumulated in a parasitic capacitance upon the light emitting operation performed immediately before the light receiving operation by the electroluminescence element; and
detecting light inputted from the outside to the inputting and outputting apparatus based on an output from the predetermined pixel including the electroluminescence element whose charge has been removed from the parasitic capacitance thereof by the process at the removing step.

6. A recording medium on which a program readable by and to be executed by a computer for controlling an inputting and outputting apparatus of an active matrix driving type including pixels each including an electroluminescence element whose operation can be changed over between light emitting operation and light receiving operation in response to a voltage applied thereto is recorded, said program comprising steps of:
removing controlling, when the light receiving operation is to be performed by the electroluminescence element included in a predetermined pixel, removal of charge accumulated in a parasitic capacitance upon the light emitting operation performed immediately before the light receiving operation by the electroluminescence element; and
detecting light inputted from the outside to the inputting and outputting apparatus based on an output from the predetermined pixel including the electroluminescence element whose charge has been removed from the parasitic capacitance thereof by the process at the removing controlling step.

7. A program for being executed by a computer for controlling an inputting and outputting apparatus of an active matrix driving type including pixels each including an electroluminescence element whose operation can be changed over between light emitting operation and light receiving operation in response to a voltage applied thereto is recorded, comprising steps of:
removing controlling, when the light receiving operation is to be performed by the electroluminescence element included in a predetermined pixel, removal of charge accumulated in a parasitic capacitance upon the light emitting operation performed immediately before the light receiving operation by the electroluminescence element; and
detecting light inputted from the outside to the inputting and outputting apparatus based on an output from the predetermined pixel including the electroluminescence element whose charge has been removed from the parasitic capacitance thereof by the process at the removing controlling step.

8. An inputting and outputting apparatus of an active matrix driving type which comprises pixels each including an electroluminescence element whose operation can be changed over between light emitting operation and light receiving operation in response to a voltage applied thereto, each of said pixels including:
a discharging unit for discharging, when the light receiving operation is to be performed, charge accumulated in a parasitic capacitance of the electroluminescence element upon light emitting operation immediately before the light receiving operation under the control of a controlling apparatus; and
an outputting unit for outputting a signal representative of current generated in the pixel in response to light illuminated thereupon from the outside.

9. A controlling apparatus for controlling an inputting and outputting apparatus of an active matrix driving type including pixels each including an electroluminescence element whose operation can be changed over between light emitting operation and light receiving operation in response to a voltage applied thereto, comprising:
a removing unit for removing, when the light receiving operation is to be performed by the electroluminescence element included in a predetermined pixel, charge accumulated in a parasitic capacitance upon the light emitting operation performed immediately before the light receiving operation by the electroluminescence element; and
a detection unit for detecting light inputted from the outside to the inputting and outputting apparatus based on an output from the predetermined pixel including the electroluminescence element whose charge has been removed from the parasitic capacitance thereof by said removing unit.
